(19) United States
(12) Patent Application Publication
(10) Pub. No.: US 2023/0371204 A1
(43) Pub. Date: Nov. 16, 2023

(54) THERMAL ENERGY MANAGEMENT SYSTEM AND METHOD FOR COMPONENT OF AN ELECTRIFIED VEHICLE

(71) Applicant: Ford Global Technologies, LLC, Dearborn, MI (US)

(72) Inventors: Moon Young Lee, Livonia, MI (US); Fan Wang, Novi, MI (US); John Casci, Westland, MI (US); Baoming Ge, Okemos, MI (US)

(21) Appl. No.: 17/740,448

(22) Filed: May 10, 2022

(51) Int. Cl. H05K 7/20

(52) U.S. Cl. CPC H05K 7/20336; H05K 7/20881; H05K 7/20854

(57) ABSTRACT

A thermal energy management system for an electrified vehicle component includes an electronic component, a heat sink, and at least one heat pipe configured to communicate thermal energy from the electronic component to the heat sink to cool the electronic component.

### TECHNICAL FIELD

This disclosure relates generally to managing thermal energy levels within components of an electrified vehicle, more particularly, to managing the thermal energy levels using at least one heat pipe.

### BACKGROUND

Electrified vehicles differ from conventional motor vehicles because electrified vehicles include a drivetrain having one or more electric machines. The electric machines can drive the electrified vehicles instead of, or in addition to, an internal combustion engine. A traction battery can power the electric machines. The traction battery can include one or more battery modules within an enclosure. The traction battery modules can each include a plurality of individual battery cells.

### SUMMARY

In some aspects, the techniques described herein relate to a thermal energy management system for an electrified vehicle component, including: an electronic component; a heat sink; and at least one heat pipe configured to communicate thermal energy from the electronic component to the heat sink to cool the electronic component.

In some aspects, the techniques described herein relate to a system, wherein the at least one heat pipe is sandwiched between the electronic component and the heat sink.

In some aspects, the techniques described herein relate to a system, wherein the at least one heat pipe is vertically between the electronic component and the heat sink.

In some aspects, the techniques described herein relate to a system, wherein the electronic component is part of an inverter system controller.

In some aspects, the techniques described herein relate to a system, wherein the electronic component is a silicon carbide metal-oxide-semiconductor field-effect transistor.

In some aspects, the techniques described herein relate to a system, wherein the heat sink is liquid cooled.

In some aspects, the techniques described herein relate to a system, wherein the heat sink includes at least one channel for communicating a liquid coolant.

In some aspects, the techniques described herein relate to a system, wherein the heat sink is air cooled.

In some aspects, the techniques described herein relate to a system, further including a plurality of fins of the heat sink.

In some aspects, the techniques described herein relate to a system, wherein the plurality of fins are on a first side of the heat sink, and the at least one heat pipe is disposed against an opposite, second side of the heat sink.

In some aspects, the techniques described herein relate to a system, wherein the at least one heat pipe is received within a pocket of the heat sink.

In some aspects, the techniques described herein relate to a system, wherein the heat sink interfaces directly with at least three sides of the at least one heat pipe.

In some aspects, the techniques described herein relate to a thermal energy management method for an electrified vehicle component, including: using at least one heat pipe to communicate thermal energy from an electronic component to a heat sink.

In some aspects, the techniques described herein relate to a method, further including liquid cooling the heat sink.

In some aspects, the techniques described herein relate to a method, further including air cooling the heat sink.

In some aspects, the techniques described herein relate to a method, wherein the at least one heat pipe is received within a pocket of the heat sink.

In some aspects, the techniques described herein relate to a method, further including sandwiching the at least one heat pipe between the electronic component and the heat sink.

In some aspects, the techniques described herein relate to a method, wherein the electronic component is a silicon carbide metal-oxide-semiconductor field-effect transistor.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

The various features and advantages of the disclosed examples will become apparent to those skilled in the art from the detailed description. The figures that accompany the detailed description can be briefly described as follows:

FIG. 1 illustrates a side view of an electrified vehicle having a traction battery.

FIG. 2 illustrates a schematic view of a powertrain from the vehicle of FIG. 1.

FIG. 3 illustrates a perspective view of selected portions of an inverter system controller from the powertrain of FIG. 2 according to an exemplary embodiment of the present disclosure.

FIG. 4 illustrates a schematic side view of an inverter system controller according to another exemplary aspect of the present disclosure.

### DETAILED DESCRIPTION

This disclosure details exemplary methods and systems for managing thermal energy levels in components of an electrified vehicle, particularly electronic components within an Inverter System Controller (ISC) of the electrified vehicle. The methods and systems can rely on heat pipes are used to manage the thermal energy levels. A heat pipe can be a sealed pipe filled with a working fluid. The fluid can vaporize and condense within the pipe. The phase change can be relied on the transfer thermal energy from one area to another area.

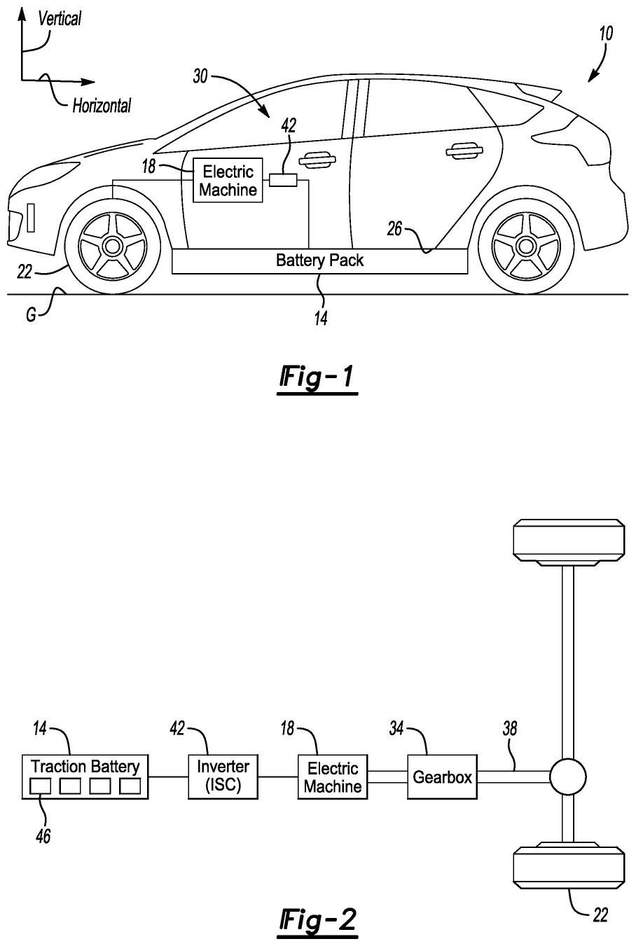

With reference to FIG. 1, an electrified vehicle 10 includes a traction battery 14, an electric machine 18, and wheels 22. The traction battery 14 powers the electric machine 18, which converts electrical power to torque to drive the wheels 22. The traction battery 14 can be recharged from the external power source. The electrified vehicle 10 can include a charge port. The traction battery 14 can be electrically coupled and recharge by an external power source through the charge port.

The electrified vehicle 10 is an all-electric vehicle. In other examples, the electrified vehicle 10 is a hybrid electric vehicle, which can selectively drive wheels using torque provided by an internal combustion engine instead, or in addition to, an electric machine. Generally, the electrified vehicle 10 can be any type of vehicle having a traction battery.

The traction battery 14 is, in the exemplary embodiment, secured to an underbody 26 of the electrified vehicle 10 vertically beneath a passenger compartment 30 of the electrified vehicle 10. Vertical, for purposes of this disclosure, is with reference to ground G and a general orientation of the electrified vehicle 10 during ordinary operation. The traction battery 14 could be located elsewhere on the electrified vehicle 10 in other examples.

With reference now to FIG. 2 and continuing reference to FIG. 1, the electric machine 18 can be connected to a gearbox 34 for adjusting the output torque and speed of the electric machine 18 by a predetermined gear ratio. The gearbox 34 can be operably connected to the wheels 22 by an output shaft 38.

The electric machine 18 is electrically coupled to the traction battery 14 through an inverter 42, which can also be referred to as an inverter system controller (ISC). The electric machine 18, the gearbox 34, and the inverter 42 may be collectively referred to as a transmission of the electrified vehicle 10.

The traction battery 14 is an exemplary electrified vehicle battery. The traction battery 14 may be a high voltage traction battery pack that includes one or more battery arrays 46 (i.e., battery assemblies or groupings of battery cells) capable of outputting electrical power to operate the electric machine 18 and/or other electrical loads of the electrified vehicle 10. Other types of energy storage devices and/or output devices can also be used to electrically power the electrified vehicle 10.

The one or more battery arrays 46 of the traction battery 14 can each include a plurality of battery cells that store energy for powering various electrical loads of the electrified vehicle 10. The traction battery 14 could employ any number of battery cells. In an embodiment, the battery cells are lithium-ion cells. However, other cell chemistries (nickel-metal hydride, lead-acid, etc.) could alternatively be utilized within the scope of this disclosure. The battery cells can include cylindrical, prismatic, or pouch battery cells. Other cell geometries could also be used.

Generally, the inverter 42 converts electricity received from the traction battery 14 from DC to AC, which is used to drive the electric machine 18. The example inverter 42 is disposed within the electrified vehicle 10 near the electric machine 18. Thermal energy levels within the inverter 42 can increase during operation. Strategies for managing these thermal energy levels have, in the past, required significant packaging space.

Reducing a packaging space for the inverter 42 can help to maintain clearances and provide space in the vehicle 10 to accommodate other items. The present disclosure details methods and systems that reduce thermal energy levels and require relatively little packaging space.

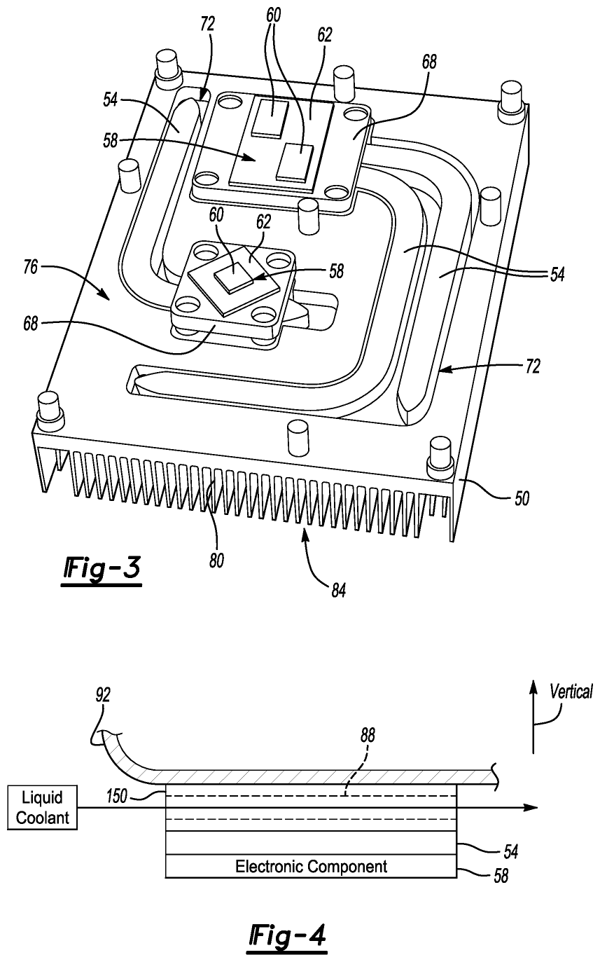

With reference now to FIG. 3 and continued reference to FIGS. 1 and 2, the inverter 42 includes, among other things, a heat sink 50, at least one heat pipe 54, and at least one electronic component 58. The at least one heat pipe 54 is sandwiched between the electronic component 58 and the heat sink 50. The at least one heat pipe 54 is, when the inverter 42 is in an installed position vertically between the electronic component 58 and the heat sink 50. In another example, the at least one heat pipe 54 is, when the inverter 42 is in the installed position, horizontally between the electronic component 58 and the heat sink 50.

The example inverter includes two heat pipes 54 and two electronic components 58. Each heat pipe 54 is configured to manage thermal energy levels within one of the electronic components 58. In particular, each heat pipe 54 is configured to communicate thermal energy from the electronic component 58 to the heat sink 50 to cool the electronic component.

In the exemplary embodiment, the electronic components 58 comprise silicon carbide metal-oxide-semiconductor field-effect transistors 60 mounted to printed circuit boards 62. The electronic components 58 are each mounted to a respective mounting plate 68, which is in direct contact with a portion of the heat pipe 54. The mounting plate can be secured to the heat sink 50 with mechanical fasteners.

As thermal energy levels in the electronic components 58 increases, the thermal energy can transfer to the respective mounting plate 68 and then to the portion of the heat pipe 54. The thermal energy can vaporize a working fluid within the portion of the heat pipe 54. The vaporized working fluid then moves to another portion of the heat pipe 54 where the working fluid condenses and transfers thermal energy to the heat sink 50.

The heat sink 50 can be a metal or metal alloy. In a specific example, the heat sink 50 is aluminum.

The heat pipes 54 are each received within a pocket 72 on a first side 76 of the heat sink 50. This enables the heat pipes 54 to directly interface with the heat sink 50 on at least three sides of the heat pipes 54. This provides more area for transfer of thermal energy than if, for example, the heat pipes 54 were to rest against a single surface of the heat pipe 54.

The example heat sink 50 is air-cooled. The heat sink 50 includes a plurality of fins 80 extending from an opposite, second side 84 of the heat sink 50. Thermal energy can transfer from the heat sink 50 to air through the fins 80.

With reference to FIG. 4, another example heat sink 150 interfaces with heat pipes 54 like the heat sink 50, but is liquid cooled rather than air-cooled. The heat sink 150 includes at least one channel 88 for communicating a liquid coolant through the heat sink 150. Thermal energy received from the heat pipes 54 is transferred to the liquid coolant and then transferred away from the heat sink 150 by the liquid coolant. Glycol liquid from the air conditioning system of the electrified vehicle 10 can be used as the coolant, for example. In another example, the coolant can be a transmission fluid. The heat sink 150 can be secured to a vehicle structure 92.

In the past, electronic components of inverter system controllers have been cooled by circulating a glycol coolant over both a top and a bottom side of the electronic components. Thermal transfer between the glycol coolant and the electronic components was relatively inefficient. The size of the electronic components was increased to compensate, which made the electronic components more expensive.

The heat pipes 54 and associated heat sink 50 or 150 provide enhanced cooling when compared to these past designs, and require less packing. Due, at least in part, to the efficiencies associated with cooling the electronic components using the heat pipes 54, the electronic components can be packaged more closely together, which can further reduce the needed packaging envelope.

Features of the disclosed examples include a thermal energy management method that facilitates a reduced packaging envelope and use of smaller electronic components. The smaller packaging envelope can provide space for a larger frunk, larger motors, the traction battery, etc.

The preceding description is exemplary rather than limiting in nature. Variations modifications to the disclosed examples may become apparent to those skilled in the art that do not necessarily depart from the essence of this disclosure. Thus, the scope of protection given to this disclosure can only be determined by studying the following claims.

What is claimed is:

1. A thermal energy management system for an electrified vehicle component, comprising:
an electronic component;
a heat sink; and
at least one heat pipe configured to communicate thermal energy from the electronic component to the heat sink to cool the electronic component.

2. The system of claim 1, wherein the at least one heat pipe is sandwiched between the electronic component and the heat sink.

3. The system of claim 2, wherein the at least one heat pipe is vertically between the electronic component and the heat sink.

4. The system of claim 1, wherein the electronic component is part of an inverter system controller.

5. The system of claim 1, wherein the electronic component is a silicon carbide metal-oxide semiconductor field-effect transistor.

6. The system of claim 1, wherein the heat sink is liquid cooled.

7. The system of claim 7, wherein the heat sink includes at least one channel for communicating a liquid coolant.

8. The system of claim 1, wherein the heat sink is air cooled.

9. The system of claim 1, further comprising a plurality of fins of the heat sink.

10. The system of claim 9, wherein the plurality of fins are on a first side of the heat sink, and the at least one heat pipe is disposed against an opposite, second side of the heat sink.

11. The system of claim 1, wherein the at least one heat pipe is received within a pocket of the heat sink.

12. The system of claim 11, wherein the heat sink interfaces directly with at least three sides of the at least one heat pipe.

13. A thermal energy management method for an electrified vehicle component, comprising:
using at least one heat pipe to communicate thermal energy from an electronic component to a heat sink.

14. The method of claim 13, further comprising liquid cooling the heat sink.

15. The method of claim 13, further comprising air cooling the heat sink.

16. The method of claim 13, wherein the at least one heat pipe is received within a pocket of the heat sink.

17. The method of claim 13, further comprising sandwiching the at least one heat pipe between the electronic component and the heat sink.

18. The method of claim 13, wherein the electronic component is a silicon carbide metal-oxide-semiconductor field-effect transistor.
